(19) United States
(12) Patent Application Publication
(10) Pub. No.: US 2024/0038827 A1
(43) Pub. Date: Feb. 1, 2024

(54) DISPLAY DEVICE

(71) Applicant: Samsung Display Co., LTD., Yongin-si (KR)

(72) Inventors: Seung Kyu LEE, Yongin-si (KR); Sae Hee RYU, Yongin-si (KR)

(73) Assignee: Samsung Display Co., LTD., Yongin-si (KR)

(21) Appl. No.: 18/326,096

(22) Filed: May 31, 2023

(30) Foreign Application Priority Data
Jul. 27, 2022 (KR) 10-2022-0093496

(51) Int. Cl. H01L 27/15; H01L 33/24; H01L 33/44; H01L 33/50

(52) U.S. Cl. CPC H01L 27/156; H01L 33/24; H01L 33/44; H01L 33/50

(57) ABSTRACT

A display device includes an alignment electrode that includes a first electrode and a second electrode surrounding the first electrode; a first organic layer disposed on the alignment electrode and including an opening partially exposing the alignment electrode; and a light emitting element provided in the opening of the first organic layer.

### CROSS-REFERENCE TO RELATED APPLICATION

This application claims priority to and benefits of Korean Patent Application No. 10-2022-0093496 under 35 U.S.C. § 119, filed in the Korean Intellectual Property Office on Jul. 27, 2022, the entire contents of which are incorporated herein by reference.

### BACKGROUND

### 1. Technical Field

The disclosure relates to a display device capable of improving display quality.

### 2. Description of the Related Art

The importance of display devices as communication media, has been emphasized because the increasing developments of information technology.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device having improved display quality.

However, embodiments of the disclosure are not limited to those set forth herein. The above and other embodiments will become more apparent to one of an ordinary skill in the art to which the disclosure pertains by referencing the detailed description of the disclosure given below.

An embodiment provides a display device including an alignment electrode including a first electrode and a second electrode surrounding the first electrode; a first organic layer disposed on the alignment electrode and including an opening partially exposing the alignment electrode; and a light emitting element provided in the opening of the first organic layer.

The display device may further include an insulating layer between the first electrode and the second electrode.

A first end portion of the light emitting element may be exposed at an upper portion of the first organic layer.

The display device may further include a connecting electrode on the first end portion of the light emitting element.

The first end portion of the light emitting element may be electrically connected to the connecting electrode.

A second end portion of the light emitting element may be electrically connected to the alignment electrode.

The second end portion of the light emitting element may be in electrical contact with the alignment electrode exposed by the opening of the first organic layer.

The display device may further include a second organic layer on the first organic layer.

The second organic layer may be provided in the opening of the first organic layer.

The second organic layer may expose the first end portion of the light emitting element.

Another embodiment provides a display device including an alignment electrode that includes a lower electrode, an upper electrode, and a core electrode between the lower electrode and the upper electrode; a first organic layer disposed on the alignment electrode and including an opening partially exposing the alignment electrode; and a light emitting element provided in the opening of the first organic layer.

The display device may further include a first insulating layer between the lower electrode and the core electrode.

The display device may further include a second insulating layer between the core electrode and the upper electrode.

The lower electrode and the upper electrode may be electrically connected to each other.

The upper electrode may be in electrical contact with the lower electrode through a contact hole penetrating the second insulating layer and the first insulating layer.

A first end portion of the light emitting element may be exposed at an upper portion of the first organic layer.

The display device may further include a connecting electrode on the first end portion of the light emitting element.

A second end portion of the light emitting element may be electrically connected to the alignment electrode exposed by the opening of the first organic layer.

The display device may further include a second organic layer on the first organic layer.

The second organic layer may expose the first end portion of the light emitting element.

Variations of other embodiments are included in the detailed description and drawings.

According to the embodiment of the disclosure, since light emitted from a light emitting element may be directly emitted to the front of a display panel by vertically aligning the light emitting element. Thus, display quality may be improved.

Effects of embodiments of the disclosure are not limited by what is illustrated in the above, and more various effects are included in the specification.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 illustrates a schematic perspective view of a light emitting element according to an embodiment;

FIG. 2 illustrates a schematic cross-sectional view of a light emitting element according to an embodiment;

FIG. 3 illustrates a schematic plan view of a display device according to an embodiment;

FIG. 4 illustrates a schematic plan view of a pixel according to an embodiment;

FIG. 5 illustrates a schematic plan view of an alignment electrode according to an embodiment;

FIG. 6 illustrates a schematic cross-sectional view taken along line A-A′ of FIG. 5;

FIG. 7 illustrates a schematic cross-sectional view taken along line B-B′ of FIG. 5;

FIG. 8 illustrates a schematic cross-sectional view taken along line C-C′ of FIG. 5;

FIG. 9 illustrates a schematic cross-sectional view of a pixel according to an embodiment;

FIG. 10 illustrates a schematic cross-sectional view of first to third pixels according to an embodiment; and

FIG. 11 illustrates a schematic cross-sectional view of a pixel according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Although the terms “first”, “second”, and the like may be used herein to describe various elements, these elements should not be limited by these terms. These terms are used to distinguish one element from another element. Thus, a first element discussed below could be termed a second element without departing from the teachings of the disclosure.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure are described in detail with reference to the accompanying drawings.

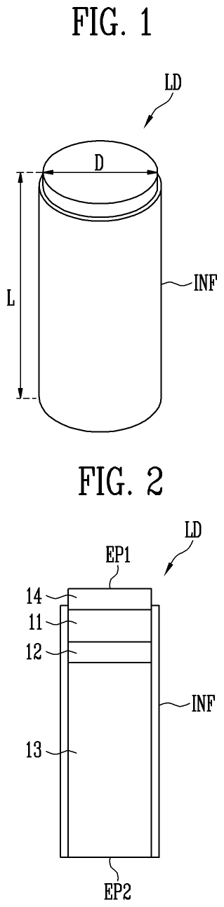

FIG. 1 illustrates a schematic perspective view of a light emitting element according to an embodiment. FIG. 2 illustrates a schematic cross-sectional view of a light emitting element according to an embodiment. FIGS. 1 and 2 illustrate a cylindrical shape light emitting element LD, but a type and/or shape of the light emitting element LD is not limited thereto.

Referring to FIGS. 1 and 2, a light emitting element LD may include a first semiconductor layer 11, an active layer 12, a second semiconductor layer 13, and/or an electrode layer 14.

The light emitting element LD may be formed to have a cylindrical shape extending in a direction. The light emitting element LD may have a first end portion EP1 and a second end portion EP2. One of the first and second semiconductor layers 11 and 13 may be disposed on the first end portion EP1 of the light emitting element LD. The remaining one of the first and second semiconductor layers 11 and 13 may be disposed on the second end portion EP2 of the light emitting element LD. For example, the first semiconductor layer 11 may be disposed on the first end portion EP1 of the light emitting element LD, and the second semiconductor layer 13 may be disposed on the second end EP2 of the light emitting element LD.

In some embodiments, the light emitting element LD may be a light emitting element manufactured in a cylindrical shape through an etching method or the like. In the specification, the “cylindrical shape” may include a rod-like shape or bar-like shape with an aspect ratio greater than about 1, such as a circular cylinder or a polygonal cylinder, but a shape of a cross-section thereof is not limited.

The light emitting element LD may have a size in a range of a nanometer scale to a micrometer scale. For example, the light emitting element LD may each have a diameter D (or width) and/or a length L in a range of a nanometer scale to a micrometer scale. However, the size of the light emitting element LD is not limited thereto, and the size of the light emitting element LD may be variously changed according to design conditions of various devices using a light emitting device using the light emitting element LD as a light source, for example, a display device.

The first semiconductor layer 11 may be a first conductive semiconductor layer. For example, the first semiconductor layer 11 may include a p-type semiconductor layer. For example, the first semiconductor layer 11 may include at least one semiconductor material of InAlGaN, GaN, AlGaN, InGaN, and AlN, and may include a p-type semiconductor layer doped with a first conductive dopant such as Mg. However, the material included in the first semiconductor layer 11 is not limited thereto, and the first semiconductor layer 11 may be made of various materials.

The active layer 12 may be disposed between the first semiconductor layer 11 and the second semiconductor layer 13. The active layer 12 may include one of a single well structure, a multi-well structure, a single quantum well structure, a multi-quantum well (MQW) structure, a quantum dot structure, and a quantum line structure, but is not limited thereto. The active layer 12 may include at least one of GaN, InGaN, InAlGaN, AlGaN, and AlN. However, the disclosure is not limited thereto, and the active layer 12 may include various other materials.

In case that a voltage of a threshold voltage or more is applied to respective ends (e.g., the first end portion EP1 and the second end portion EP2) of the light emitting element LD, electron-hole pairs may be combined in the active layer 12, and the light emitting element LD may emit light. The light emitting of the light emitting element LD may be controlled by using the principle (e.g., the combination of the electron-hole pairs), the light emitting element LD may be used as a light source for various light emitting devices in addition to pixels of a display device.

The second semiconductor layer 13 may be disposed on the active layer 12, and may include a semiconductor layer of a type different from that of the first semiconductor layer 11. The second semiconductor layer 13 may include an n-type semiconductor layer. For example, the second semiconductor layer 13 may include at least one semiconductor material of InAlGaN, GaN, AlGaN, InGaN, and AlN, and may include an n-type semiconductor layer doped with a second conductive dopant such as Si, Ge, Sn, or the like. However, the material included in the second semiconductor layer 13 is not limited thereto, and the second semiconductor layer 13 may be made of various materials.

The electrode layer 14 may be disposed on the first end portion EP1 and/or the second end portion EP2 of the light emitting element LD. In FIG. 2, the electrode layer 14 is formed on the first semiconductor layer 11, but the disclosure is not limited thereto. For example, a separate electrode layer may be further disposed on the second semiconductor layer 13.

The electrode layer 14 may include a transparent metal or transparent metal oxide. As an example, the electrode layer 14 may include at least one of an indium tin oxide (ITO), an indium zinc oxide (IZO), and a zinc tin oxide (ZTO), but is not limited thereto. In case that the electrode layer 14 is made of (or include) the transparent metal or transparent metal oxide, light generated in the active layer 12 of the light emitting element LD may transmit (or pass) through the electrode layer 14 to be emitted to the outside of the light emitting element LD.

An insulating film INF may be provided on a surface (e.g., an outer surface) of the light emitting element LD. The insulating film INF may be disposed (e.g., directly disposed) on surfaces (e.g., outer surfaces) of the first semiconductor layer 11, the active layer 12, the second semiconductor layer 13, and/or the electrode layer 14. The insulating film INF may expose the first and second end portions EP1 and EP2 of the light emitting element LD having different polarities. In some embodiments, the insulating film INF may expose side portions of the electrode layer 14 and/or the second semiconductor layer 13 that are adjacent to the first and second end portions EP1 and EP2 of the light emitting element LD.

The insulating film INF may prevent an electrical short circuit that may occur in case that the active layer 12 contacts conductive materials other than the first and second semiconductor layers 11 and 13. The insulating film INF may minimize surface defects of the light emitting elements LD, and improve lifespan and luminous efficiency of the light emitting elements LD.

The insulating film INF may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). For example, the insulating film INF may be configured as a double layer, and respective layers configuring the double layer may include different materials. For example, the insulating film INF may be formed as a double layer made of an aluminum oxide (AlOₓ) and a silicon oxide (SiOₓ), but is not limited thereto. In some embodiments, the insulating film INF may be omitted.

A light emitting device including the light emitting element LD described above may be used in various types of devices that require a light source in addition to a display device. For example, the light emitting elements LD may be disposed in each pixel of a display panel, and the light emitting elements LD may be used as a light source of each pixel. However, an application field of the light emitting element LD is not limited to the above-described example. For example, the light emitting element LD may be used in other types of devices that require a light source, such as a lighting device.

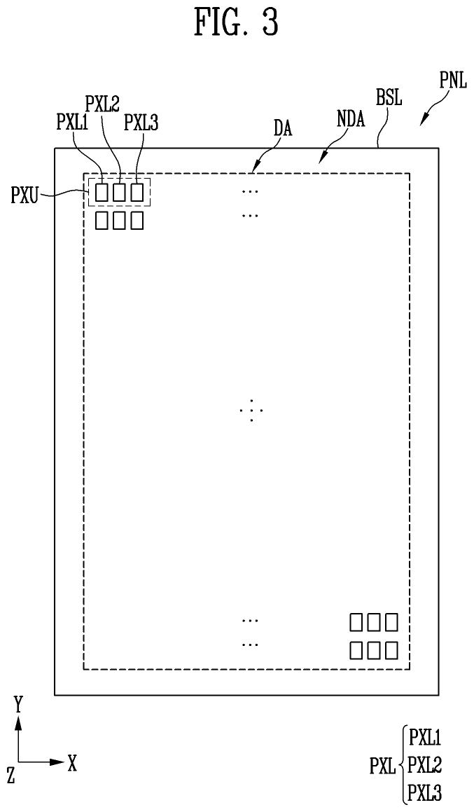

FIG. 3 illustrates a schematic plan view of a display device according to an embodiment.

FIG. 3 illustrates a display device (e.g., a display panel PNL provided in the display device) as an example of an electronic device that may use the light emitting element LD described in the embodiments of FIGS. 1 and 2 as a light source.

For better understanding and ease of description, FIG. 3 briefly illustrates a structure of the display panel PNL based on a display area DA. However, in some embodiments, at least one driving circuit portion (e.g., at least one of a scan driver and a data driver), wires, and/or pads, which are not shown, may be further disposed in the display panel PNL.

Referring to FIG. 3, the display panel PNL and a base layer BSL for forming the display panel PNL may include the display area DA for displaying an image and a non-display area NDA surrounding or adjacent to the display area DA. The display area DA may configure a screen on which an image is displayed, and the non-display area NDA may be a remaining area except for the display area DA.

A pixel part (or pixel unit) PXU may be disposed in the display area DA. The pixel part PXU may include a first pixel PXL1, a second pixel PXL2, and/or a third pixel PXL3 Hereinafter, when arbitrarily referring to at least one of the first pixel PXL1, the second pixel PXL2, and the third pixel PXL3, or when comprehensively referring to two or more types of pixels thereof, they will be referred to as a “pixel PXL” or “pixels PXL”.

The pixels PXL may be regularly arranged according to a stripe or PENTILE™ arrangement structure. However, the arrangement structure of the pixels PXL is not limited thereto, and the pixels PXL may be arranged in the display area DA in various structures and/or methods.

In some embodiments, two or more types of pixels PXL emitting lights of different colors may be disposed in the display area DA. For example, in the display area DA, multiple first pixels PXL1 emitting light of a first color, multiple second pixels PXL2 emitting light of a second color, and multiple third pixels PXL3 emitting light of a third color may be arranged. At least one first pixel PXL1, at least one second pixel PXL2, and at least one third pixel PXL3 adjacent to each other may form a pixel part PXU that may emit lights of various colors. For example, each of the first to third pixels PXL1, PXL2, and PXL3 may be a pixel that emits a light of a color (e.g., a predetermined or selectable color). In some embodiments, the first pixel PXL1 may be a red pixel that emits red light, the second pixel PXL2 may be a green pixel that emits green light, and the third pixel PXL3 may be a blue pixel that emits blue light, but the disclosure is not limited thereto.

In the embodiment, the first pixel PXL1, the second pixel PXL2, and the third pixel PXL3 may be provided with light emitting elements of a same color, and include color converting layers and/or color filter layers of different colors disposed on respective light emitting elements. Thus, the first to third pixels PXL1, PXL2, and PXL3 may emit light of the first color, the second color, and the third color, respectively. In another embodiment, the first pixel PXL1, the second pixel PXL2, and the third pixel PXL3 may be each provided with a first color light emitting element, a second color light emitting element, and a third color light emitting element as a light source, respectively, so that they respectively emit light of the first color, second color, and third color. However, the color, type, and/or number of pixels PXL configuring each pixel part PXU are not limited thereto. For example, the color of light emitted by each pixel PXL may be variously changed.

The pixel PXL may include at least one light source driven by a control signal (e.g., a scan signal and a data signal) and/or a power source (e.g., a first power source and a second power source). In the embodiment, the light source may include at least one light emitting element LD according to one of the embodiments of FIGS. 1 and 2. For example, the light source may include ultra-small cylindrical shape light emitting elements LD having a size in a range of a nanometer scale to a micrometer scale. However, the disclosure is not limited thereto, and various types of light emitting elements LD may be used as a light source of the pixel PXL.

In the embodiment, each pixel PXL may be configured as an active pixel. However, the type, structure, and/or driving method of pixels PXL that may be applied to the display device are not limited thereto. For example, each pixel PXL may be configured as a pixel of a passive or active light emitting display device of various structures and/or driving methods.

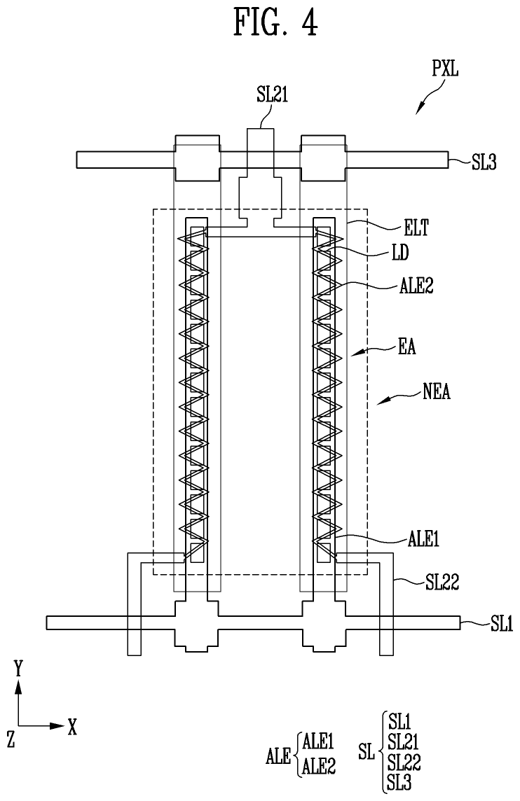

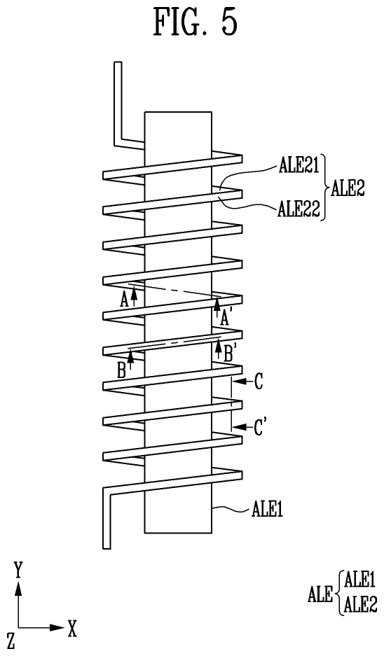

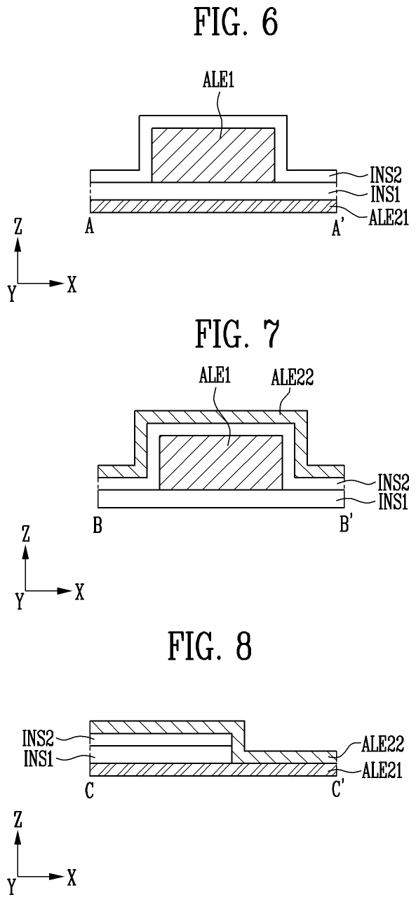

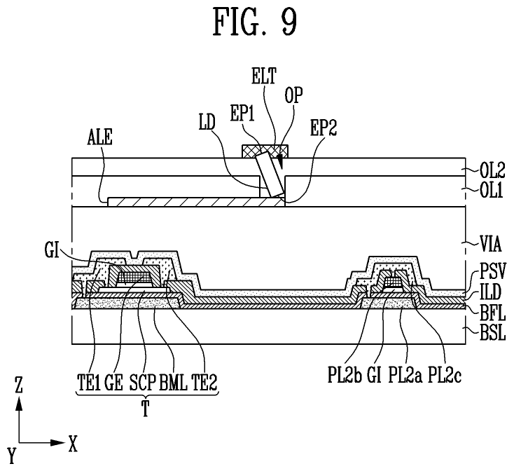

FIG. 4 illustrates a schematic plan view of a pixel according to an embodiment. FIG. 5 illustrates a schematic plan view of an alignment electrode according to an embodiment. FIG. 6 illustrates a schematic cross-sectional view taken along line A-A′ of FIG. 5. FIG. 7 illustrates a schematic cross-sectional view taken along line B-B′ of FIG. 5. FIG. 8 illustrates a schematic cross-sectional view taken along line C-C′ of FIG. 5. FIG. 9 illustrates a schematic cross-sectional view of a pixel according to an embodiment.

As an example, FIG. 4 may be one of the first to third pixels PXL1, PXL2, and PXL3 configuring the pixel part PXU of FIG. 3, and the first to third pixels PXL1, PXL2, and PXL3 may be substantially the same or similar to each other.

Referring to FIGS. 4 to 8, the pixel PXL may include a light emitting area EA and a non-light emitting area NEA. The light emitting elements LD may be disposed in the light emitting area EA, and the light emitting area EA may be an area that may emit light. The light emitting area EA may be adjacent to (e.g., surrounded by) the non-light emitting area NEA.

The pixel PXL may include alignment electrodes ALE, the light emitting elements LD, connecting electrodes ELT, and/or signal lines SL.

The alignment electrodes ALE may be provided in at least part of the light emitting area EA. The alignment electrode ALE may include a first electrode ALE1 and a second electrode ALE2. The second electrode ALE2 may be adjacent to (e.g., surround) the first electrode ALE1. For example, each of the alignment electrodes ALE may be an electromagnet. The first electrode ALE1 may correspond to a core electrode of the electromagnet, and the second electrode ALE2 may correspond to a coil electrode of the electromagnet. For example, in case that a current flows through the second electrode ALE2, a magnetic field may be generated to form a polarity (e.g., a certain or selectable polarity). The second electrode ALE2 may include lower electrodes ALE21 and upper electrodes ALE22. The lower electrodes ALE21 may be spaced apart from each other under the first electrode ALE1. The upper electrodes ALE22 may be spaced apart from each other above the first electrode ALE1. For example, the first electrode ALE1 may be positioned between the lower electrode ALE21 and the upper electrode ALE22. A first insulating layer INS1 may be disposed between the lower electrode ALE21 and the first electrode ALE1. A second insulating layer INS2 may be disposed between the first electrode ALE1 and the upper electrode ALE22. The lower electrode ALE21 and the upper electrode ALE22 may be electrically connected to each other. An end of the upper electrode ALE22 may be in contact with an end of an adjacent lower electrode ALE21 through a contact hole passing through the second insulating layer INS2 and the first insulating layer INS1. Another end of the lower electrode ALE21 may be in contact with the another end of an adjacent upper electrode ALE22 through a contact hole passing through the second insulating layer INS2 and the first insulating layer INS1. As described above, in case that the upper electrode ALE22 and the lower electrode ALE21 are alternately connected, the second electrode ALE2 may be adjacent to (e.g., surround) the first electrode ALE1 in a coil shape. In case that the alignment electrode ALE is configured as an electromagnet in the above-described manner, the alignment electrode ALE may have a constant polarity to vertically align the light emitting elements LD.

The first electrode ALE1 may be electrically connected to a first signal line SL1. The first signal line SL1 may extend in a first direction (e.g., in an X-axis direction) in the non-light emitting area NEA, but is not limited thereto. The lower electrode ALE21 of the second electrode ALE2 may be electrically connected to a second lower signal line SL21. The upper electrode ALE22 of the second electrode ALE2 may be electrically connected to a second upper signal line SL22. Each of the second lower signal line SL21 and the second upper signal line SL22 may extend in a second direction (e.g., in a Y-axis direction) in the non-light emitting area NEA, but is not limited thereto.

The light emitting elements LD may be aligned on the alignment electrode ALE in the light emitting area EA. The light emitting elements LD may be electrically connected to the alignment electrode ALE. The light emitting elements LD may be prepared in a form dispersed in light emitting element ink, and may be supplied to the light emitting area EA of each pixel PXL through an inkjet printing method and the like. For example, the light emitting elements LD may be dispersed in a volatile solvent and provided in the light emitting area EA of each pixel PXL. In case that a current flows through the alignment electrode ALE, a magnetic field may be generated to form a constant polarity, and the light emitting element LD may be vertically aligned by an attractive force of the alignment electrode ALE. In some embodiments, in the process of aligning the light emitting element LD, ultraviolet UV may be irradiated onto the light emitting element LD and induce a polarity of the light emitting element LD. Thus, the light emitting element LD may be readily vertically aligned. After the light emitting elements LD are vertically aligned, the solvent may be volatilized (or eliminated in other ways), and the light emitting elements LD may be stably arranged on the alignment electrode ALE.

The connecting electrodes ELT may be disposed on the light emitting elements LD. The connecting electrodes ELT may be provided in at least part of the light emitting area EA. The connecting electrodes ELT may be electrically connected to the light emitting elements LD. The connecting electrodes ELT may extend in the second direction (e.g., in a Y-axis direction), and may be spaced apart from each other in the first direction (e.g., in the X-axis direction).

The connecting electrode ELT may be electrically connected to a third signal line SL3. The third signal line SL3 may extend in the first direction (e.g., in the X-axis direction) in the non-light emitting area NEA, but is not limited thereto.

Hereinafter, detailed description of a cross-sectional structure of the pixel PXL is provided with reference to FIG. 9. FIG. 9 illustrates a transistor T among various circuit elements configuring a pixel circuit. However, a structure and/or a position of each layer of the transistor T are not limited to the embodiment illustrated in FIG. 9, and may be variously changed according to embodiments.

Referring to FIG. 9, the pixels PXL (e.g., refer to FIG. 3) according to the embodiment may include circuit elements including the transistor T disposed on the base layer BSL and various wires electrically connected thereto. The alignment electrode ALE, the light emitting element LD, and/or the connecting electrode ELT may be disposed on the circuit elements.

The base layer BSL may configure a base member and may be a rigid or flexible substrate (or film). For example, the base layer BSL may be a hard substrate made of glass or tempered glass, a flexible substrate (or a thin film) made of a plastic or metallic material, or at least one layered insulating layer. The material and/or physical properties of the base layer BSL are not limited thereto.

A lower conductive layer BML and a first power conductive layer PL2a may be disposed on the base layer BSL. The lower conductive layer BML and the first power conductive layer PL2a may be disposed on a same layer. For example, the lower conductive layer BML and the first power conductive layer PL2a may be simultaneously formed in a same process, but the disclosure is not limited thereto.

Each of the lower conductive layer BML and the first power conductive layer PL2a may be formed as a single layer or multilayer including at least one of molybdenum (Mo), copper (Cu), aluminum (Al), chromium (Cr), gold (Au), titanium (Ti), nickel (Ni), neodymium (Nd), indium (In), tin (Sn), and an oxide thereof or an alloy thereof.

A buffer layer BFL may be disposed on the lower conductive layer BML and the first power conductive layer PL2a. The buffer layer BFL may prevent impurities from diffusing into the circuit element. The buffer layer BFL may be formed as a single layer, but may also be formed as a multilayer of at least double layers or more. In case that the buffer layer BFL is formed as the multilayer, respective layers may be made of a same material or different materials.

A semiconductor pattern SCP may be disposed on the buffer layer BFL. For example, the semiconductor pattern SCP may include a first area contacting a first transistor electrode TE1, a second area contacting a second transistor electrode TE2, and a channel area disposed between the first and second areas. In some embodiments, one of the first and second areas of the semiconductor pattern SCP may be a source area, and the other thereof may be a drain area.

In some embodiments, the semiconductor pattern SCP may include at least one of polysilicon, amorphous silicon, and an oxide semiconductor, or the like. The channel area of the semiconductor pattern SCP may be an intrinsic semiconductor as a semiconductor pattern that is not doped with impurities, and each of the first and second areas of the semiconductor pattern SCP may be a semiconductor doped with impurities.

A gate insulating layer GI may be disposed on the buffer layer BFL and the semiconductor pattern SCP. For example, the gate insulating layer GI may be disposed between the semiconductor pattern SCP and a gate electrode GE. The gate insulating layer GI may be disposed between the buffer layer BFL and a second power conductive layer PL2b. The gate insulating layer GI may be configured as a single layer or multilayer, and may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). However, the disclosure is not limited thereto, and the gate insulating layer GI may include various types of inorganic materials.

The gate electrode GE of the transistor T and the second power conductive layer PL2b may be disposed on the gate insulating layer GI. The gate electrode GE and the second power conductive layer PL2b may be disposed on a same layer. For example, the gate electrode GE and the second power conductive layer PL2b may be simultaneously formed in a same process, but the disclosure is not limited thereto. The gate electrode GE may overlap the semiconductor pattern SCP in a third direction (e.g., in a Z-axis direction) on the gate insulating layer GI. The second power conductive layer PL2b may be disposed to overlap the first power conductive layer PL2a on the gate insulating layer GI in the third direction (e.g., in the Z-axis direction).

Each of the gate electrode GE and the second power conductive layer PL2b may be formed as a single layer or multilayer including at least one of molybdenum (Mo), copper (Cu), aluminum (Al), chromium (Cr), gold (Au), titanium (Ti), nickel (Ni), neodymium (Nd), indium (In), and tin (Sn). In other embodiments, each of the gate electrode GE and the second power conductive layer PL2b may include an oxide thereof or an alloy thereof. For example, each of the gate electrode GE and the second power conductive layer PL2b may be formed as a multilayer in which titanium (Ti), copper (Cu), and/or an indium tin oxide (ITO) are sequentially or repeatedly stacked one another.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and a third power conductive layer PL2c.

The interlayer insulating layer ILD may be configured as a single layer or multilayer, and may include at least one of silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). In other embodiments, the interlayer insulating layer ILD may include various types of inorganic materials.

The first and second transistor electrodes TE1 and TE2 of the transistor T and the third power conductive layer PL2c may be disposed on the interlayer insulating layer ILD. The first and second transistor electrodes TE1 and TE2 and the third power conductive layer PL2c may be disposed on a same layer. For example, the first and second transistor electrodes TE1 and TE2 and the third power conductive layer PL2c may be simultaneously formed in a same process, but are not limited thereto.

The first and second transistor electrodes TE1 and TE2 may be disposed to overlap the semiconductor pattern SCP in the third direction (e.g., in the Z-axis direction). The first and second transistor electrodes TE1 and TE2 may be electrically connected to the semiconductor pattern SCP. For example, the first transistor electrode TE1 may be electrically connected to the first area of the semiconductor pattern SCP through a contact hole penetrating the interlayer insulating layer ILD. The first transistor electrode TE1 may be electrically connected to the lower conductive layer BML through a contact hole penetrating the interlayer insulating layer ILD and the buffer layer BFL. The second transistor electrode TE2 may be electrically connected to the second area of the semiconductor pattern SCP through a contact hole penetrating the interlayer insulating layer ILD. In some embodiments, one of the first and second transistor electrodes TE1 and TE2 may be a source electrode, and another thereof may be a drain electrode.

The third power conductive layer PL2c may overlap the first power conductive layer PL2a and/or the second power conductive layer PL2b in the third direction (e.g., in the Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole penetrating the interlayer insulating layer ILD and the buffer layer BFL. The third power conductive layer PL2c may be electrically connected to the second power conductive layer PL2b through a contact hole penetrating the interlayer insulating layer ILD.

The first and second transistor electrodes TE1 and TE2 and the third power conductive layer PL2c may be formed as a single layer or multilayer including at least one of molybdenum (Mo), copper (Cu), aluminum (Al), chromium (Cr), gold (Au), titanium (Ti), nickel (Ni), neodymium (Nd), indium (In), tin (Sn), and an oxide thereof or an alloy thereof.

A passivation layer PSV may be disposed on the first and second transistor electrodes TE1 and TE2 and the third power conductive layer PL2c. The passivation layer PSV may be configured as a single layer or multilayer, and may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). However, the disclosure is not limited thereto, and the passivation layer PSV may include various types of inorganic materials.

A via layer VIA may be disposed on the passivation layer PSV. The via layer VIA may be made of an organic material and flatten (or planarize) a lower step thereof. For example, the via layer VIA may include at least one organic material such as an acrylates resin, an epoxy resin, a phenolic resin, a polyamides resin, a polyimide resin, a polyesters resin, a polyphenylenesulfides resin, or a benzocyclobutene (BCB). However, the disclosure is not limited thereto, and the via layer VIA may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). For example, the via layer VIA may include various types of inorganic materials.

The alignment electrode ALE may be disposed on the via layer VIA. In case that a current flows through the alignment electrode ALE, a magnetic field may be generated to form a constant polarity, and the light emitting elements LD may be vertically aligned by an attractive force of the alignment electrode ALE.

The alignment electrode ALE may include at least one conductive material. For example, the alignment electrodes ALE may include at least one of metal, a conductive oxide, and a conductive material. The metal of the alignment electrodes ALE may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu). For example, the alignment electrodes ALE may include an alloy including the above-described metals. The conductive oxide of the alignment electrodes ALE may include at least one of an indium tin oxide (ITO), an indium zinc oxide (IZO), an indium tin zinc Oxide (ITZO), an aluminum zinc oxide (AZO), a gallium zinc oxide (GZO), a zinc tin oxide (ZTO), and a gallium tin oxide (GTO). The conductive material of the alignment electrodes ALE may include conductive polymers such as PEDOT. However, the disclosure is not limited thereto.

A first organic layer OL1 may be disposed on the alignment electrode ALE. The first organic layer OL1 may include at least one organic material of an acrylates resin, an epoxy resin, a phenolic resin, a polyamides resin, a polyimide resin, a polyesters resin, a polyphenylenesulfides resin, and a benzocyclobutene (BCB), but is not limited thereto.

The first organic layer OL1 may include an opening OP partially exposing the alignment electrode ALE. The opening OP may provide a space in which the light emitting elements LD may be aligned in the supplying of the light emitting elements LD to the pixel PXL. For example, during a manufacturing process of the display device, the light emitting elements LD may be supplied and aligned in the opening OP. For example, the light emitting element LD may be vertically aligned in the opening OP.

The light emitting elements LD may be prepared in a form dispersed in light emitting element ink and may be supplied to each pixel PXL through an inkjet printing method and the like. For example, the light emitting elements LD may be dispersed in a volatile solvent and provided in each pixel PXL. In case that a current flows through the alignment electrode ALE, a magnetic field may be generated to form a constant polarity, and the light emitting elements LD may be vertically aligned on the alignment electrode ALE. For example, the first end portion EP1 (or first semiconductor layer) of the light emitting element LD may be aligned to face the third direction (e.g., the Z-axis direction), and the second end portion EP2 (or second semiconductor layer) of the light emitting element LD may be aligned to face a direction opposite to the third direction (e.g., the Z-axis direction). The first end portion EP1 (or first semiconductor layer) of the light emitting element LD may be exposed at an upper portion of the first organic layer OL1, and the second end portion EP2 (or second semiconductor layer) of the light emitting element LD may be positioned on the alignment electrode ALE exposed by the opening OP. For example, the second end portion EP2 (or second semiconductor layer) of the light emitting element LD may be in contact with the alignment electrode ALE exposed by the opening OP. The second end portion EP2 (or second semiconductor layer) of the light emitting element LD may be electrically connected to the alignment electrode ALE.

As described above, the light emitting elements LD may be vertically aligned, and the first end portion EP1 (or first semiconductor layer) of the light emitting element LD having a large amount of emitted light may be disposed to face the third direction (e.g., the Z-axis direction) or a front surface of the display panel PNL. For example, an amount of light emitted from the first end portion EP1 may be greater than an amount of light emitted from the second end portion EP2, and the first end portion EP1 of the light emitting element LD may be aligned in the third direction (e.g., in the Z-axis direction). Thus, luminance of the display device in the third direction (e.g., in the Z-axis direction) may be improved. Accordingly, since light emitted from the light emitting element LD (e.g., the light emitted from the first end portion EP1 of the light emitting element LD) may be emitted (e.g., directly emitted) to the front surface of the display panel PNL, a separate reflective member may be omitted. For example, loss of light due to a reflective output light structure, color mixing defects, or deterioration of image quality due to reflection of external light may be prevented, and the display quality may be improved.

A second organic layer OL2 may be disposed on the first organic layer OL1. The second organic layer OL2 may include at least one organic material such as an acrylates resin, an epoxy resin, a phenolic resin, a polyamides resin, a polyimide resin, a polyesters resin, a polyphenylenesulfides resin, and a benzocyclobutene (BCB), but is not limited thereto.

The second organic layer OL2 may cover a side surface of the light emitting element LD, and expose the first end portion EP1 of the light emitting element LD. A portion of the second organic layer OL2 may be provided in the opening OP and fix the light emitting element LD.

The connecting electrode ELT may be disposed on the second organic layer OL2. The connecting electrode ELT may be in contact with the first end portion EP1 of the light emitting element LD exposed by the second organic layer OL2. The connecting electrode ELT may be electrically connected to the first end portion EP1 of the light emitting element LD.

The connecting electrode ELT may be made of various transparent conductive materials. For example, the connecting electrode ELT may include at least one transparent conductive material of an indium tin oxide (ITO), an indium zinc oxide (IZO), an indium tin zinc oxide (ITZO), an aluminum zinc oxide (AZO), a gallium zinc oxide (GZO), a zinc tin oxide (ZTO), and a gallium tin oxide (GTO). Accordingly, the light emitted from the light emitting elements LD may pass through the connecting electrode ELT, and may be emitted to the front surface of the display panel PNL.

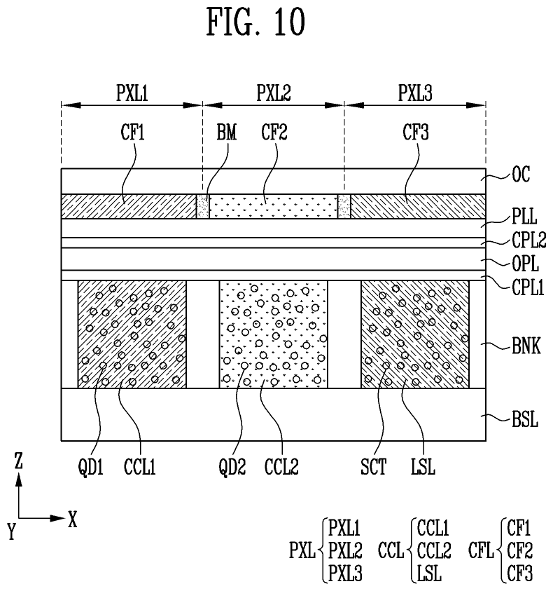

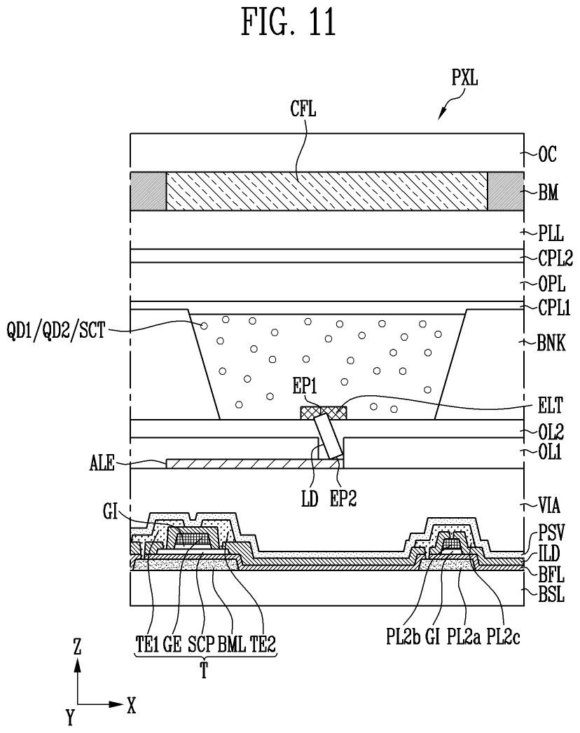

FIG. 10 illustrates a schematic cross-sectional view of first to third pixels according to an embodiment. FIG. 11 illustrates a schematic cross-sectional view of a pixel according to an embodiment.

FIG. 10 illustrates a color converting layer CCL, an optical layer OPL, a color filter layer CFL, and the like. In FIG. 10, for better understanding and ease of description, detailed description of the same constituent elements except for the base layer BSL of FIG. 9 is omitted. FIG. 11 schematically illustrates a stacked structure of the pixel PXL, which includes the color converting layer CCL, the optical layer OPL, and/or the color filter layer CFL.

Referring to FIGS. 10 and 11, a bank BNK may be disposed between the first to third pixels PXL1, PXL2, and PXL3 or at a boundary therebetween. The bank BNK may include an opening overlapping the first to third pixels PXL1, PXL2, and PXL3 in a plan view, respectively. The opening of the bank BNK may provide a space in which the color converting layer CCL may be provided.

The bank BNK may include at least one organic material of an acrylates resin, an epoxy resin, a phenolic resin, a polyamides resin, a polyimide resin, a polyesters resin, a polyphenylenesulfides resin, and a benzocyclobutene (BCB). However, the disclosure is not limited thereto, and the bank BNK may be configured as a single layer or multilayer. In other embodiments, the bank BNK may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). For example, the bank BNK may include various types of inorganic materials.

In some embodiments, the bank BNK may include at least one light blocking material and/or light reflective material. Accordingly, light leakage between adjacent pixels PXL may be prevented. For example, the bank BNK may include at least one black pigment.

The color converting layer CCL may be disposed on the light emitting elements LD in the opening of the bank BNK. The color converting layer CCL may include a first color converting layer CCL1 disposed on the first pixel PXL1, a second color converting layer CCL2 disposed on the second pixel PXL2, and a scattering layer LSL disposed on the third pixel PXL3 In the embodiment, the first to third pixels PXL1, PXL2, and PXL3 may include the light emitting elements LD that emit light of a same color. For example, the first to third pixels PXL1, PXL2, and PXL3 may include the light emitting elements LD that emit light of a third color (or blue color). The color converting layer CCL including color converting particles may be disposed on the first to third pixels PXL1, PXL2, and PXL3, respectively. Thus, a full-color image may be displayed.

The first color converting layer CCL1 may include first color converting particles that convert light of the third color emitted from the light emitting element LD into the light of the first color. For example, the first color converting layer CCL1 may include first quantum dots QD1 dispersed in a matrix material such as a base resin.

In the embodiment, in case that the light emitting element LD is a blue light emitting element that emits blue light and the first pixel PXL1 is a red pixel, the first color converting layer CCL1 may include a first quantum dot QD1 that converts blue light emitted from the blue light emitting element into red light. The first quantum dot QD1 may absorb blue light to shift a wavelength according to an energy transition to emit red light. In case that the first pixel PXL1 is a pixel of a different color, the first color converting layer CCL1 may include a first quantum dot QD1 corresponding to a color of the first pixel PXL1.

The second color converting layer CCL2 may include second color converting particles that convert light of the third color emitted from the light emitting element LD into light of the second color. For example, the second color converting layer CCL2 may include second quantum dots QD2 dispersed in a matrix material such as a base resin.

In the embodiment, in case that the light emitting element LD is a blue light emitting element that emits blue light and the second pixel PXL2 is a green pixel, the second color converting layer CCL2 may include a second quantum dot QD2 that converts blue light emitted from the blue light emitting element into green light. The second quantum dot QD2 may absorb blue light to shift a wavelength according to an energy transition to emit green light. In case that the second pixel PXL2 is a pixel of a different color, the second color converting layer CCL2 may include the second quantum dot QD2 corresponding to a color of the second pixel PXL2.

In the embodiment, blue light having a relatively short wavelength among the visible ray bands may be incident on the first quantum dot QD1 and the second quantum dot QD2, respectively. Thus, absorption coefficient of the first quantum dot QD1 and the second quantum dot QD2 may be increased. Accordingly, the efficiency of light emitted from the first pixel PXL1 and the second pixel PXL2 may be increased, and at a same time, the excellent color reproducibility may be secured. The light emitting part EMU of the first to third pixels PXL1, PXL2, and PXL3 may be configured by using the light emitting elements LD of a same color (e.g., the blue color light emitting element), and the manufacturing efficiency of the display device may be increased.

The scattering layer LSL may be provided to efficiently use the third color (or blue color) light emitted from the light emitting element LD. For example, in case that the light emitting element LD is a blue light emitting element that emits blue light and the third pixel PXL3 is a blue pixel, the scattering layer LSL may include at least one type of scatterer SCT to efficiently use the light emitted from the light emitting element LD. For example, the scatterer SCT of the scattering layer LSL may include at least one of a barium sulfate (BsSO₄), a calcium carbonate (CaCO₃), a titanium oxide TiO₂, a silicon oxide SiO₂, an aluminum oxide (Al₂O₃), a zirconium oxide ZrO₂, and a zinc oxide (ZnO). In other embodiments, the scatterer SCT may not be disposed only in the third pixel PXL3, and may be selectively included in the first color converting layer CCL1 or the second color converting layer CCL2. In some embodiments, the scatterer SCT may be omitted to provide the scattering layer LSL made of a transparent polymer.

A first capping layer CPL1 may be disposed on the color converting layer CCL. The first capping layer CPL1 may be disposed (e.g., entirely disposed) on the first to third pixels PXL1, PXL2, and PXL3. The first capping layer CPL1 may cover the color converting layer CCL. The first capping layer CPL1 may prevent impurities such as moisture or air from penetrating from the outside to damage or contaminate the color converting layer CCL.

The first capping layer CPL1 may be an inorganic layer, which may include at least one of a silicon nitride (SiNₓ), an aluminum nitride (AlNₓ), a titanium nitride (TiNₓ), a silicon oxide (SiOₓ), an aluminum oxide (AlOₓ), a titanium oxide (TiOₓ), a silicon oxycarbide (SiOₓC_{y}), and a silicon oxynitride (SiOₓN_{y}).

The optical layer OPL may be disposed on the first capping layer CPL1. The optical layer OPL may serve to improve light extraction efficiency by recycling light provided from the color converting layer CCL by total reflection. To this end, the optical layer OPL may have a relatively low refractive index compared to the color converting layer CCL. For example, the refractive index of the color converting layer CCL may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be disposed (e.g., entirely disposed) on the first to third pixels PXL1, PXL2, and PXL3. The second capping layer CPL2 may cover the optical layer OPL. The second capping layer CPL2 may prevent impurities such as moisture or air from penetrating from the outside to damage or contaminate the optical layer OPL.

The second capping layer CPL2 may be an inorganic layer, which may include at least one of a silicon nitride (SiNₓ), an aluminum nitride (AlNₓ), a titanium nitride (TiNₓ), a silicon oxide (SiOₓ), an aluminum oxide (AlOₓ), a titanium oxide (TiOₓ), a silicon oxycarbide (SiOₓC_{y}), and a silicon oxynitride (SiOₓN_{y}).

A planarization layer PLL may be disposed on the second capping layer CPL2. The planarization layer PLL may be provided (e.g., entirely provided) in the first to third pixels PXL1, PXL2, and PXL3

The planarization layer PLL may include an organic material such as an acrylic resin, an epoxy resin, a phenolic resin, a polyamide resin, a polyimide rein, a polyester resin, a polyphenylenesulfide resin, or a benzocyclobutene (BCB). However, the disclosure is not limited thereto, and the planarization layer PLL may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). For example, the planarization layer PLL may include various types of inorganic materials.

The color filter layer CFL may be disposed on the planarization layer PLL. The color filter layer CFL may include color filters CF1, CF2, and CF3 matching the color of each pixel PXL. The color filters CF1, CF2, and CF3 matching respective colors of the first to third pixels PXL1, PXL2, and PXL3 may be disposed in the first to third pixels PXL1, PXL2, and PXL3, and a full-color image may be displayed.

The color filter layer CFL may include a first color filter CF1, a second color filter CF2, and a third color filter CF3. The first color filter CF1 may be disposed in the first pixel PXL1 and selectively transmit (or pass) light emitted by the first pixel PXL1. The second color filter CF2 may be disposed in the second pixel PXL2 and selectively transmit (or pass) light emitted by the second pixel PXL2. The third color filter CF3 may be disposed in the third pixel PXL3 and selectively transmit (or pass) light emitted by the third pixel PXL3.

In the embodiment, the first color filter CF1, the second color filter CF2, and the third color filter CF3 may be a red color filter, a green color filter, and a blue color filter respectively, but the disclosure is not limited thereto. Hereinafter, when referring to one of the first color filter CF1, the second color filter CF2, and the third color filter CF3, or when comprehensively referring to two or more thereof, it will be referred to as the “color filter CF” or “color filters CF”.

The first color filter CF1 may overlap the first color converting layer CCL1 in the third direction (e.g., in the Z-axis direction). The first color filter CF1 may include a color filter material that selectively transmits (or passes) a light of a first color (or red color). For example, in case that the first pixel PXL1 is a red pixel, the first color filter CF1 may include a red color filter material.

The second color filter CF2 may overlap the second color converting layer CCL2 in the third direction (e.g., in the Z-axis direction). The second color filter CF2 may include a color filter material that selectively transmits (or passes) a light of a second color (or green color). For example, in case that the second pixel PXL2 is a green pixel, the second color filter CF2 may include a green color filter material.

The third color filter CF3 may overlap the scattering layer LSL in the third direction (e.g., in the Z-axis direction). The third color filter CF3 may include a color filter material that selectively transmits (or passes) a light of a third color (or blue color). For example, in case that the third pixel PXL3 is a blue pixel, the third color filter CF3 may include a blue color filter material.

In some embodiments, a light blocking layer BM may be further disposed between the first to third color filters CF1, CF2, and CF3, and in this case, in case that the light blocking layer BM is formed between the first to third color filters CF1, CF2, and CF3, it is possible to prevent a color mixing defect viewed from a front or side of a display device. A material of a light blocking layer BM is not limited thereto, and may be made of various light blocking materials. For example, the light blocking layer BM may be implemented by stacking the first to third color filters CF1, CF2, and CF3 on each other.

An overcoat layer OC may be disposed on the color filter layer CFL. The overcoat layer OC may be provided (e.g., entirely provided) in the first to third pixels PXL1, PXL2, and PXL3. The overcoat layer OC may cover the color filter layer CFL and a lower member thereof. The overcoat layer OC may prevent moisture or air from penetrating into the above-mentioned lower members that are disposed therebelow. The overcoat layer OC may protect the above-mentioned lower members from foreign matters such as dust.

The overcoat layer OC may include an organic material such as an acrylic resin, an epoxy resin, a phenolic resin, a polyamide resin, a polyimide rein, a polyester resin, a polyphenylenesulfide resin, or a benzocyclobutene (BCB). However, the disclosure is not limited thereto, and the overcoat layer OC may include at least one of a silicon oxide (SiOₓ), a silicon nitride (SiNₓ), a silicon oxynitride (SiOₓN_{y}), an aluminum nitride (AlNₓ), an aluminum oxide (AlOₓ), a zirconium oxide (ZrOₓ), a hafnium oxide (HfOₓ), and a titanium oxide (TiOₓ). For example, the overcoat layer OC may include various types of inorganic materials.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an alignment electrode including:
a first electrode; and
a second electrode surrounding the first electrode;
a first organic layer disposed on the alignment electrode and including an opening partially exposing the alignment electrode; and
a light emitting element provided in the opening of the first organic layer.

2. The display device of claim 1, further comprising:
an insulating layer between the first electrode and the second electrode.

3. The display device of claim 2, wherein a first end portion of the light emitting element is exposed at an upper portion of the first organic layer.

4. The display device of claim 3, further comprising:
a connecting electrode on the first end portion of the light emitting element.

5. The display device of claim 4, wherein the first end portion of the light emitting element is electrically connected to the connecting electrode.

6. The display device of claim 5, wherein a second end portion of the light emitting element is electrically connected to the alignment electrode.

7. The display device of claim 6, wherein the second end portion of the light emitting element is in electrical contact with the alignment electrode exposed by the opening of the first organic layer.

8. The display device of claim 7, further comprising:
a second organic layer on the first organic layer.

9. The display device of claim 8, wherein the second organic layer is provided in the opening of the first organic layer.

10. The display device of claim 9, wherein the second organic layer exposes the first end portion of the light emitting element.

11. A display device comprising:
an alignment electrode including:
a lower electrode;
an upper electrode; and
a core electrode between the lower electrode and the upper electrode;
a first organic layer disposed on the alignment electrode and including an opening partially exposing the alignment electrode; and
a light emitting element provided in the opening of the first organic layer.

12. The display device of claim 11, further comprising:
a first insulating layer between the lower electrode and the core electrode.

13. The display device of claim 12, further comprising:
a second insulating layer between the core electrode and the upper electrode.

14. The display device of claim 13, wherein the lower electrode and the upper electrode are electrically connected to each other.

15. The display device of claim 14, wherein the upper electrode is in electrical contact with the lower electrode through a contact hole penetrating the second insulating layer and the first insulating layer.

16. The display device of claim 15, wherein a first end portion of the light emitting element is exposed at an upper portion of the first organic layer.

17. The display device of claim 16, further comprising:
a connecting electrode on the first end portion of the light emitting element.

18. The display device of claim 17, wherein a second end portion of the light emitting element is electrically connected to the alignment electrode exposed by the opening of the first organic layer.

19. The display device of claim 18, further comprising:
a second organic layer on the first organic layer.

20. The display device of claim 19, wherein the second organic layer exposes the first end portion of the light emitting element.
